(19) United States
(12) Patent Application Publication
(10) Pub. No.: US 2022/0365114 A1
(43) Pub. Date: Nov. 17, 2022

(54) Electrical Discharge Detection System

(71) Applicant: NITTO KOGYO CORPORATION, Nagakute-shi (JP)

(72) Inventor: Atsushi Miyamoto, Nagakute-shi (JP)

(21) Appl. No.: 17/773,155

(22) PCT Filed: Oct. 30, 2020
(86) PCT No.: PCT/JP2020/040790

§ 371 Date: Apr. 29, 2022

(30) Foreign Application Priority Data
Nov. 1, 2019 (JP) 2019-199501

(51) Int. Cl. G01R 19/00; G01R 19/165; G01R 31/58; G01R 31/327

(52) U.S. Cl. CPC G01R 19/0053; G01R 19/16571; G01R 19/16585; G01R 31/58; G01R 31/3277

(57) ABSTRACT

A discharge detection system of the present invention includes a current detection section configured to detect a value of current flowing in a circuit; a high pass filter configured to detect noise in a high frequency band superimposed on the circuit by a discharge phenomenon; and a determination section electrically connected to the current detection section and the high pass filter. The determination section executes steps including determining whether the discharge phenomenon has occurred based on the noise in the high frequency band detected by the high pass filter, when the discharge phenomenon is determined to have occurred, calculating an increase or decrease in the current value at the occurrence of the discharge phenomenon based on the current value detected by the current detection section, and specifying information on the discharge phenomenon based on the increase or decrease in the current value.

### CROSS-REFERENCE TO RELATED APPLICATIONS

This application is the United States national phase of International Application No. PCT/JP2020/040790 filed Oct. 30, 2020, and claims priority to Japanese Patent Application No. 2019-199501 filed Nov. 1, 2019, the disclosures of which are hereby incorporated by reference in their entirety.

### BACKGROUND OF THE INVENTION

### Field of the Invention

The present invention relates to a discharge detection system.

### Description of Related Art

Japanese Patent Application Kokai Publication No. 2017-173008 discloses a system to detect high frequency noise generated by a discharge phenomenon using a CR circuit. The CR circuit is configured to connect a capacitor and a resistor in series and is electrically connected between different electrodes in a circuit. Such a CR circuit passes noise components at a predetermined frequency or more. Measurement of the value of the voltage applied to both ends of the resistor in the CR circuit allows detection of discharge phenomena.

### PRIOR ART DOCUMENTS

### Patent Document

Patent Document 1: Japanese Patent Application Kokai Publication No. 2017-173008

Discharge phenomena occur by causes such as disconnection and a short circuit, for example. Although being capable of detecting a discharge phenomenon, the system in the past described above is not capable of specifying the cause of the discharge phenomenon. Users of the system thus have to specify the cause of the discharge phenomenon by examining the states of indoor wiring, electrical appliances, plugs, plug sockets, and the like after the discharge phenomenon is detected.

### SUMMARY OF THE INVENTION

### Problems to be Solved by the Invention

The present invention has been made in view of the above problems and it is an object thereof to provide a discharge detection system that is capable of specifying information on a detected discharge phenomenon and is capable of facilitating specification of the cause of the discharge phenomenon by a user.

### Means to Solve the Problems

(1) To achieve the above object, a discharge detection system of the present invention includes: a current detection section configured to detect a value of current flowing in a circuit; a high pass filter configured to detect noise in a high frequency band superimposed on the circuit by a discharge phenomenon; and a determination section electrically connected to the current detection section and the high pass filter, wherein the determination section executes process including determining whether the discharge phenomenon has occurred based on the noise in the high frequency band detected by the high pass filter, when the discharge phenomenon is determined to have occurred, calculating an increase or decrease in the current value at the occurrence of the discharge phenomenon based on the current value detected by the current detection section, and specifying information on the discharge phenomenon based on the increase or decrease in the current value.

(2) It is preferred that, in the discharge detection system according to (1) above, a plurality of time periods are set in accordance with magnitude of the current value, the determination section executes, when the discharge phenomenon is determined to have occurred, process to output a cutoff signal after the time period has passed set in accordance with the magnitude of the current value at the occurrence of the discharge phenomenon, and a switch electrically connected to the circuit turns into an open state based on the cutoff signal to interrupt power supply to the circuit.

(3) It is preferred that, in the discharge detection system according to (1) or (2) above, the high pass filter is electrically connected to the determination section via first wiring, the current detection section is electrically connected to the determination section via second wiring, and the determination section determines whether the discharge phenomenon has occurred based on the noise in the high frequency band input via the first wiring and calculates the increase or decrease in the current value at the occurrence of the discharge phenomenon based on the current value input via the second wiring.

(4) It is preferred that, in the discharge detection system according to any of (1) through (3) above, the determination section executes process including: specifying the discharge phenomenon to have occurred between different electrodes when the current value at the occurrence of the discharge phenomenon increases; and specifying the discharge phenomenon to have occurred between identical electrodes when the current value at the occurrence of the discharge phenomenon decreases.

### Effects of the Invention

The discharge detection system of the present invention is capable of specifying information on a detected discharge phenomenon based on an increase or decrease in the current value at the occurrence of the discharge phenomenon. The information facilitates specification of the cause of the discharge phenomenon by a user.

### BRIEF DESCRIPTION OF THE DRAWINGS

FIG. 1 is a circuit diagram illustrating a breaker provided with a discharge detection system according to a first embodiment of the present invention.

FIG. 2A is a diagram illustrating the waveform of current detected by a current detection section. FIG. 2B is a diagram illustrating the waveform of current passing through a high pass filter.

FIG. 3A is a schematic diagram illustrating the state in which a plug of a load is electrically connected to a plug socket. FIG. 3B is a circuit diagram omitting the plug and the plug socket in FIG. 3A.

FIG. 4A is a schematic diagram illustrating the state in which disconnection occurs between the load and the plug. FIG. 4B is a circuit diagram omitting the plug and the plug socket in FIG. 4A.

FIG. 5 is a diagram illustrating the waveform of current detected by the current detection section while instantaneous disconnection as illustrated in FIG. 4A occurs a plurality of times.

FIG. 6A is a schematic diagram illustrating the state in which a small short circuit occurs near the plug. FIG. 6B is a circuit diagram omitting the plug and the plug socket in FIG. 6A.

FIG. 7 is a diagram illustrating the waveform of current detected by the current detection section while small short circuits as illustrated in FIG. 5 instantaneously occur a plurality of times.

FIG. 8 is a circuit diagram illustrating a breaker provided with a discharge detection system according to a second embodiment of the present invention.

FIG. 9 is a circuit diagram illustrating a discharge detection system according to a third embodiment of the present invention and a breaker provided separately from the discharge detection system.

### DESCRIPTION OF THE INVENTION

1. First Embodiment

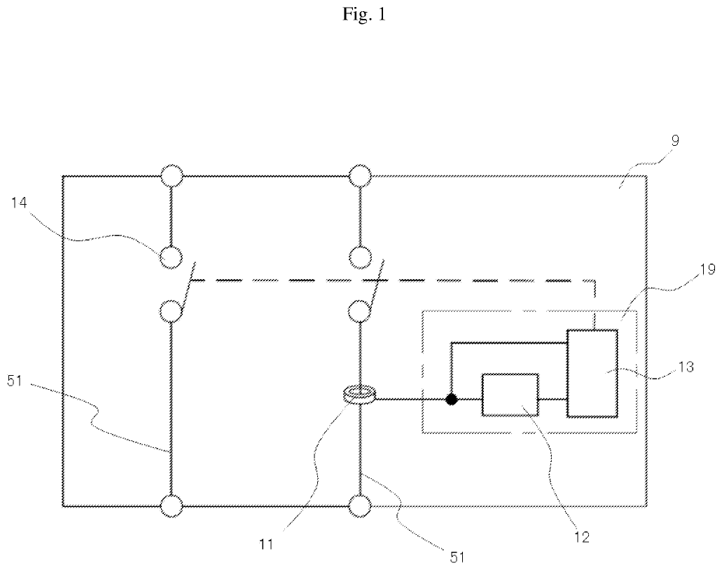

At first, with reference to FIGS. 1 through 7, a description is given to a discharge detection system according to the first embodiment of the present invention.

A breaker 9 illustrated in FIG. 1 is provided with a discharge detection system 19 in the present embodiment. The breaker 9 is electrically connected to, for example, indoor wiring of a building. The power provided by a power company is supplied to lighting fixtures, plug sockets, and the like provided in the building via the breaker 9. The breaker 9 is provided with switches 14. The switches 14 turn into an open state when current greater than a given value flows in the breaker 9 to interrupt the power supply to the indoor wiring. In this situation, the switches 14 in the present embodiment turn into an open state based on a cutoff signal output from the discharge detection system 19. This issue is detailed later.

The discharge detection system 19 in the present embodiment is configured with a current detection section 11, a high pass filter 12, and a determination section 13.

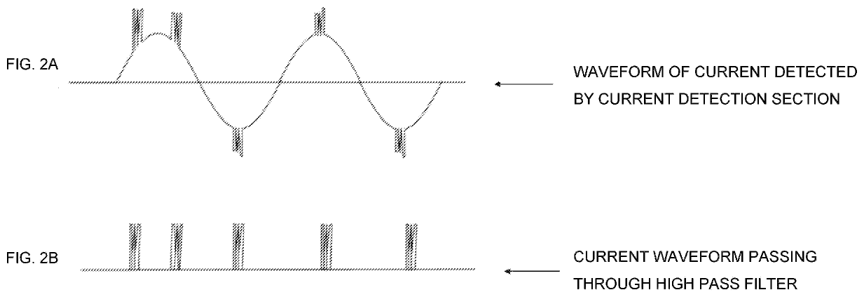

The current detection section 11 detects current flowing in wiring 51 of the breaker 9. The current detection section 11 is, for example, a current transformer and has a configuration of winding a secondary winding on an annular core. Through the annular core, the wiring 51 subjected to the current measurement passes. The secondary winding feeds secondary current in proportion to primary current flowing in the primary wiring. FIG. 2A illustrates the waveform of the current detected by the current detection section 11.

The high pass filter 12 is electrically connected to the current detection section 11 and the determination section 13. The high pass filter 12 passes noise in a frequency band higher than a cutoff frequency generated in an alternating circuit. When a discharge phenomenon occurs, the noise in the higher frequency band is superimposed on output from the current detection section 11. The high pass filter 12 detects the noise in the higher frequency band for output to the determination section 13. FIG. 2B illustrates the waveform of the current passing through the high pass filter 12.

The determination section 13 is electrically connected to the current detection section 11 and the high pass filter 12. To the determination section 13, the current detected by the current detection section 11 and the noise in the higher frequency band having passed through the high pass filter 12 are input. In the present embodiment, the wiring electrically connecting the current detection section 11 with the high pass filter 12 is branched in the middle to directly input the current detected by the current detection section 11 to the determination section 13.

The determination section 13 determines whether a discharge phenomenon has occurred based on the noise in the higher frequency band having passed through the high pass filter 12. For example, the determination section 13 determines that a discharge phenomenon has occurred if the noise in the higher frequency band having passed through the high pass filter 12 is greater than a predetermined threshold during a predetermined time period.

Meanwhile, the determination section 13 calculates an increase or decrease in the value of the current detected by the current detection section 11 at the timing the discharge phenomenon occurs. The determination section 13 then specifies information on the detected discharge phenomenon based on the increase or decrease in the current value. The information facilitates specification of the cause of the discharge phenomenon by a user.

Here, the technical significance of combining the current detection section 11 with the high pass filter 12 is described.

In the first place, the combination of the current detection section 11 with the high pass filter 12 allows detection of occurrence of a discharge phenomenon. That is, in the wiring 51, alternating current flows. The alternating current originally has a waveform of a regular sine wave. If a discharge phenomenon occurs, noise in the higher frequency band is superimposed on the alternating current, resulting in irregular sine waves of the alternating current. It is thus considered that monitoring of the waveform of the current detected by the current detection section 11 allows detection of occurrence of a discharge phenomenon.

However, various electrical appliances (load 62) are connected to the indoor wiring of the building. Noise is also generated when the load 62 is switched ON/OFF. The noise is also superimposed on the alternating current flowing in the wiring 51, causing an irregular sine wave of the alternating current. It is thus not possible to detect occurrence of a discharge phenomenon only by monitoring the waveform of the current detected by the current detection section 11. Accordingly, in the present embodiment, results of detection by the current detection section 11 are filtered with the high pass filter 12 to select only noise in the higher frequency band caused by discharge phenomena. It is thus possible to detect occurrence of such a discharge phenomenon.

In the second place, combination of the current detection section 11 with the high pass filter 12 allows specification of information on the detected discharge phenomenon. That is, the information on the detected discharge phenomenon is specified based on an increase or decrease in the current value at the timing the discharge phenomenon occurs. As illustrated in FIGS. 2A and 2B, the timing the discharge phenomenon occurs is equal to the timing the high pass filter 12 detects the noise in the higher frequency band. It is thus possible to determine the cause of the discharge phenomenon by calculating an increase or decrease in the current value at the timing the high pass filter 12 detects the noise in the higher frequency band. Moreover, it is possible to estimate the degree of danger of the discharge phenomenon based on the magnitude of the current value at the timing the discharge phenomenon occurs.

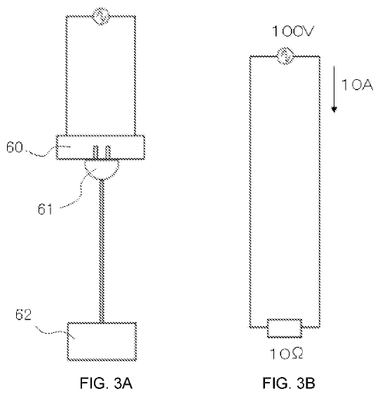

The information on the detected discharge phenomenon includes, for example, the type and cause of the discharge phenomenon. With reference to FIGS. 3A through 7, the types and causes of discharge phenomena are described. There are two types of discharge phenomena: discharge phenomena occurring between identical electrodes and discharge phenomena occurring between different electrodes.

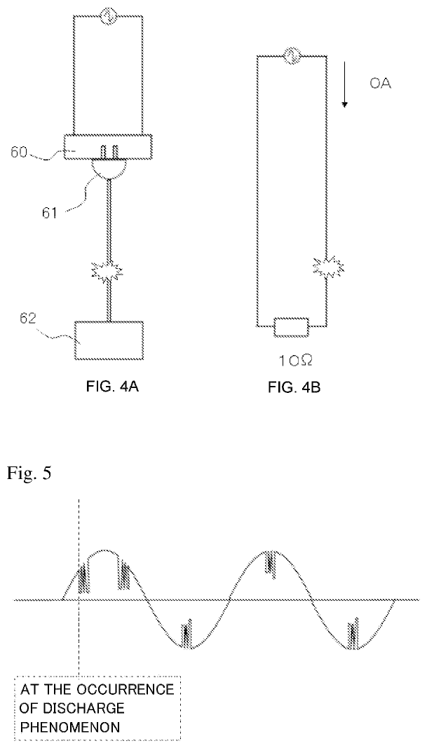

At first, the discharge phenomena occurring between identical electrodes are described. FIGS. 3A and 3B illustrate the state in which a plug 61 of the load 62 is electrically connected to a plug socket 60. FIGS. 4A and 4B illustrate the state in which disconnection occurs between the load 62 and the plug 61. The cause of the discharge phenomena occurring between identical electrodes is disconnection. If disconnection occurs, current is less likely to flow. As illustrated in the current waveform of FIG. 5, the current value at the occurrence of a discharge phenomenon between identical electrodes thus decreases from the current value before the occurrence of the discharge phenomenon. The current waveform has concave irregularities partially in the sine wave.

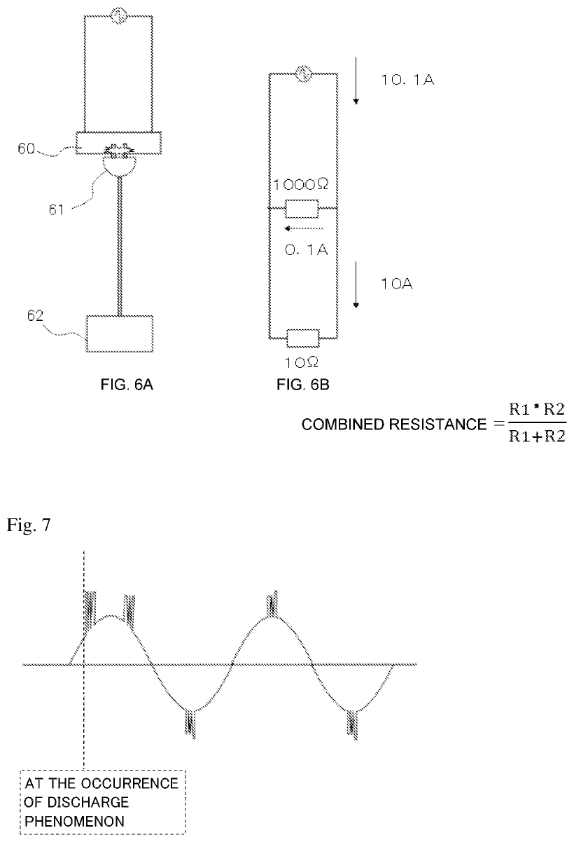

Then, the discharge phenomena occurring between different electrodes are described. FIGS. 6A and 6B illustrate the state in which a small short circuit occurs near the plug 61. The cause of the discharge phenomena occurring between different electrodes is a short circuit. If a short circuit occurs, current is likely to flow. As illustrated in the current waveform of FIG. 7, the current value at the occurrence of the discharge phenomenon between different electrodes thus increases from the current value before the occurrence of the discharge phenomenon. The current waveform has convex irregularities partially in the sine wave.

As just described, it is possible to specify the type and cause of the discharge phenomenon based on the increase or decrease in the current value at the timing the discharge phenomenon occurs. More specifically, the determination section 13 illustrated in FIG. 1 specifies, when the current value increases at the timing a discharge phenomenon occurs, the discharge phenomenon to have occurred between different electrodes and specifies, when the current value decreases at that timing, the discharge phenomenon to have occurred between identical electrodes. The discharge phenomenon between different electrodes means that a short circuit has occurred. The discharge phenomenon between identical electrodes means that disconnection has occurred. A user can readily draw the cause of the discharge phenomenon by being provided with information on whether the detected discharge phenomenon has occurred between different electrodes or between identical electrodes.

In this situation, when a discharge phenomenon is determined to have occurred, the determination section 13 outputs a cutoff signal. The cutoff signal is input to a mechanical section of each switch 14 electrically connected to the wiring 51. The mechanical section causes the switch 14 to operate and turn into an open state based on the cutoff signal. The power supply to the indoor wiring is thus interrupted.

The determination section 13 may perform process of varying the timing of outputting a cutoff signal in accordance with the magnitude of the current value at the timing a discharge phenomenon occurs. As described above, the magnitude of the current value at the timing the discharge phenomenon occurs indicates the degree of danger of the discharge phenomenon. It is considered that a larger current value indicates that the discharge phenomenon is more dangerous and a smaller current value indicates that the discharge phenomenon is less dangerous. Accordingly, a larger current value causes the determination section 13 to output a cutoff signal in a shorter period of time after the occurrence of the discharge phenomenon, and a smaller current value causes the determination section 13 to output a cutoff signal in a longer period of time after the occurrence of the discharge phenomenon. This causes the switches 14 to be in an open state at a timing in accordance with the degree of danger of the discharge phenomenon. In other words, if the discharge phenomenon is more dangerous, the breaker 9 is quickly interrupted. In contrast, if the discharge phenomenon is less dangerous, the breaker 9 is interrupted with delay.

The determination section 13 measures the magnitude of the current value at the timing the discharge phenomenon occurs based on the result of detection by either the current detection section 11 or the high pass filter 12. The current value may be either an effective value or an average value. For example, the current value at the timing a discharge phenomenon occurs is assumed as 5 A, 10 A, 16 A, or 32 A. In the case of 5 A, a cutoff signal is output 1 second after the discharge phenomenon occurred. In the case of 10 A, a cutoff signal is output 0.4 seconds after the discharge phenomenon occurred. In the case of 16 A, a cutoff signal is output 0.28 seconds after the discharge phenomenon occurred. In the case of 32 A, a cutoff signal is output 0.14 seconds after the discharge phenomenon occurred. In the case of 32 A or more, a cutoff signal may be output uniformly 0.14 seconds after the discharge phenomenon occurred. As another example, in the case of greater than 32 A, a cutoff signal may be output in a period of time shorter than 0.14 seconds in accordance with the current value. It should be noted that the relationship between the magnitude of the current value and the time period before a cutoff signal is output is not particularly limited.

2. Second Embodiment

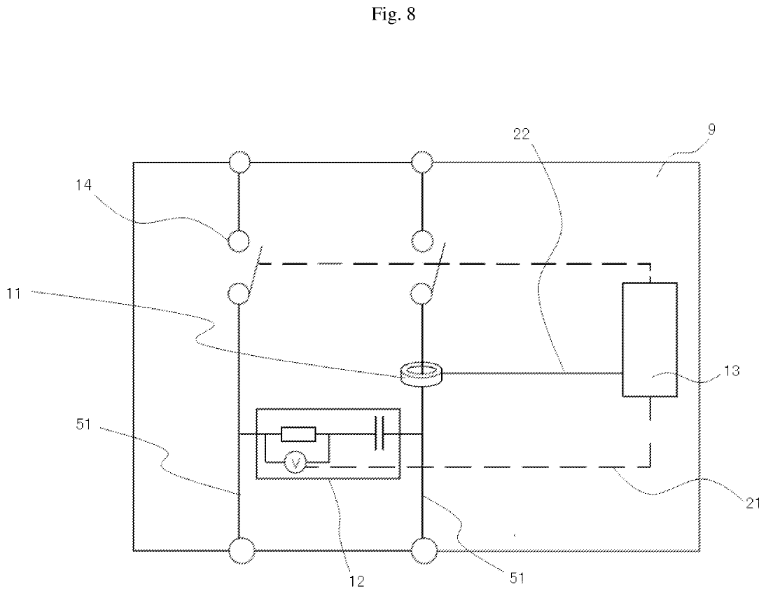

FIG. 8 illustrates a breaker 9 provided with a discharge detection system according to the second embodiment of the present invention. The discharge detection system 19 in the first embodiment illustrated in FIG. 1 is configured to electrically connect the high pass filter 12 to the current detection section 11. In contrast, the discharge detection system in the second embodiment illustrated in FIG. 8 is configured to electrically connect the high pass filter 12 between the wiring 51 of the different electrodes.

As illustrated in FIG. 8, the high pass filter 12 is electrically connected to the determination section 13 via first wiring 21. Noise in a higher frequency band detected by the high pass filter 12 is input to the determination section 13 via the first wiring 21. Meanwhile, the current detection section 11 is electrically connected to the determination section 13 via second wiring 22. The waveform of current detected by the current detection section 11 is input to the determination section 13 via the second wiring 22.

As just described, in the discharge detection system of the second embodiment, the high pass filter 12 is electrically connected to the determination section 13 separately from the current detection section 11. The determination section 13 determines whether a discharge phenomenon has occurred based on the result of detection by the high pass filter 12 input from the first wiring 21. The determination section 13 also determines an increase or decrease in the current value based on the result of detection by the current detection section 11 input from the second wiring 22. The first wiring 21 and the second wiring 22 are independent of each other and the result of detection by the high pass filter 12 is not influenced by the result of detection by the current detection section 11. It should be noted that the high pass filter 12 may be configured to be electrically connected to the primary side of the current detection section 11 in the wiring 51.

3. Third Embodiment

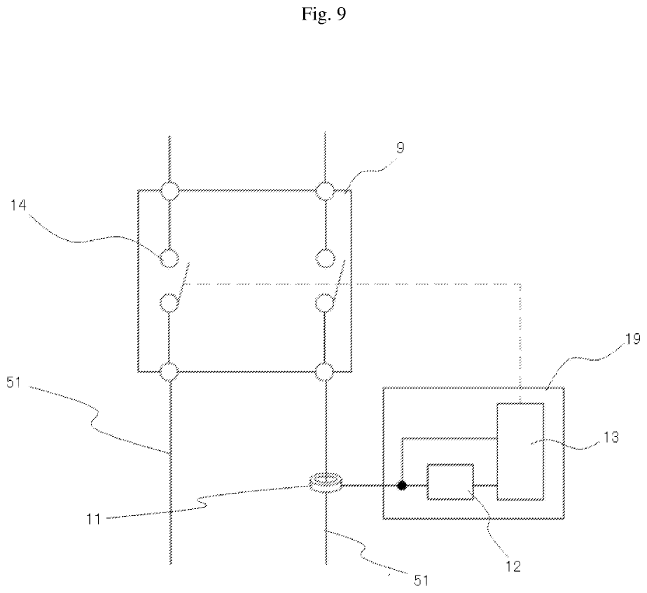

FIG. 9 illustrates a discharge detection system 19 according to the third embodiment of the present invention and a breaker 9 provided separately from the discharge detection system 19. Both discharge detection systems in the first and second embodiments illustrated in FIGS. 1 and 8 are provided in the breaker 9. In contrast, the discharge detection system 19 in the third embodiment illustrated in FIG. 9 may be an independent apparatus provided separately from the breaker 9.

The discharge detection system of the present invention is not limited to the configuration in the first through third embodiments described above and the configuration may be variously altered. For example, the current detection section 11 illustrated in FIG. 1 or 9 may be included in the unit of the discharge detection system 19 together with the high pass filter 12 and the determination section 13.

### DESCRIPTION OF REFERENCE NUMERALS

9 Breaker
11 Current Detection Section
12 High Pass Filter
13 Determination Section
14 Switch
19 Discharge Detection System
21 First Wiring
22 Second Wiring
51 Wiring

1. A discharge detection system comprising:
a current detection section configured to detect a value of current flowing in a circuit;
a high pass filter configured to detect noise in a high frequency band superimposed on the circuit by a discharge phenomenon; and
a determination section electrically connected to the current detection section and the high pass filter, wherein
the determination section executes steps including
determining whether the discharge phenomenon has occurred based on the noise in the high frequency band detected by the high pass filter,
when the discharge phenomenon is determined to have occurred, calculating an increase or decrease in the current value at the occurrence of the discharge phenomenon based on the current value detected by the current detection section, and
specifying information on the discharge phenomenon based on the increase or decrease in the current value.

2. The discharge detection system according to claim 1, wherein
a plurality of time periods are set in accordance with magnitude of the current value,
the determination section executes, when the discharge phenomenon is determined to have occurred, steps to output a cutoff signal after the time period has passed set in accordance with the magnitude of the current value at the occurrence of the discharge phenomenon, and
a switch electrically connected to the circuit turns into an open state based on the cutoff signal to interrupt power supply to the circuit.

3. The discharge detection system according to claim 1, wherein
the high pass filter is electrically connected to the determination section via first wiring,
the current detection section is electrically connected to the determination section via second wiring, and
the determination section determines whether the discharge phenomenon has occurred based on the noise in the high frequency band input via the first wiring and calculates the increase or decrease in the current value at the occurrence of the discharge phenomenon based on the current value input via the second wiring.

4. The discharge detection system according to claim 1, wherein the determination section executes steps including:
specifying the discharge phenomenon to have occurred between different electrodes when the current value at the occurrence of the discharge phenomenon increases; and
specifying the discharge phenomenon to have occurred between identical electrodes when the current value at the occurrence of the discharge phenomenon decreases.

5. The discharge detection system according to claim 2, wherein
the high pass filter is electrically connected to the determination section via first wiring,
the current detection section is electrically connected to the determination section via second wiring, and
the determination section determines whether the discharge phenomenon has occurred based on the noise in the high frequency band input via the first wiring and calculates the increase or decrease in the current value at the occurrence of the discharge phenomenon based on the current value input via the second wiring.

6. The discharge detection system according to claim 2, wherein the determination section executes steps including:
specifying the discharge phenomenon to have occurred between different electrodes when the current value at the occurrence of the discharge phenomenon increases; and
specifying the discharge phenomenon to have occurred between identical electrodes when the current value at the occurrence of the discharge phenomenon decreases.

7. The discharge detection system according to claim 3, wherein the determination section executes steps including:
specifying the discharge phenomenon to have occurred between different electrodes when the current value at the occurrence of the discharge phenomenon increases; and
specifying the discharge phenomenon to have occurred between identical electrodes when the current value at the occurrence of the discharge phenomenon decreases.

8. The discharge detection system according to claim 5, wherein the determination section executes steps including
specifying the discharge phenomenon to have occurred between different electrodes when the current value at the occurrence of the discharge phenomenon increases; and
specifying the discharge phenomenon to have occurred between identical electrodes when the current value at the occurrence of the discharge phenomenon decreases.
